(19) United States
(12) Patent Application Publication
(10) Pub. No.: US 2023/0314528 A1
(43) Pub. Date: Oct. 5, 2023

(54) Method of Estimation of Battery Degradation

(71) Applicant: ABB Schweiz AG, Baden (CH)

(72) Inventors: Kacper Sowa, Barcice (PL); Adam Ruszczyk, Kraków (PL); Carlos Nieto, Jüri (PL)

(73) Assignee: ABB Schweiz AG, Baden (CH)

(21) Appl. No.: 18/185,473

(22) Filed: Mar. 17, 2023

(30) Foreign Application Priority Data
Mar. 18, 2022 (EP) 22163101.3

(51) Int. Cl. G01R 31/392; G01R 31/382; G01R 31/367

(52) U.S. Cl. CPC G01R 31/392; G01R 31/367; G01R 31/382

(57) ABSTRACT

A method for estimating battery degradation includes acquiring battery parameters, characteristics of calendar ageing wearing, cycle ageing wearing coefficient BWC2, wherein BWC1 is a function of State of Charge and BWC2 is a function of charging/dis-charging rate, acquiring and/or calculating instantaneous values of SoC and C-rate of a battery in a defined period, reading instantaneous values of calendar ageing wearing coefficient BWC1 and/or instantaneous values of cycle ageing wearing coefficient BWC2 corresponding to instantaneous values of SoC and C-rate of a battery acquired previously, using characteristics of calendar ageing wearing coefficients acquired and determining value of calendar ageing wearing index BWI1 by referring integrated instantaneous values of BWC1 determined to the integrated instantaneous values of BWC1 for a period of nominal operation time with maximum allowable value of the SoC.

### CROSS-REFERENCE TO RELATED APPLICATIONS

This patent application claims priority to European Patent Application No. 22163101.3, filed on Mar. 18, 2022, which is incorporated herein in its entirety by reference.

### FIELD OF THE DISCLOSURE

The present disclosure relates to a method of estimation of battery degradation, in particular battery degradation in battery energy storage systems (BESS). The method is suitable for the estimation of degradation of any kind of battery, notably Li-Ion battery in battery energy storage systems (BESS) designated to support energy distribution or energy flow of power systems, in particular power systems with high dynamic loads.

### BACKGROUND OF THE INVENTION

Nowadays plenty of devices and applications require to store electric energy in different forms of storages. It entails either balancing of instantaneous energy consumption over a defined period (peak shaving) or mobile usage of devices such as portable devices or electric vehicles.

The most popular are electrochemical batteries especially Li-Ion type due to the highest energy density per volume or mass and practically lack of memory effect. Nevertheless, chemical batteries degrade over time and during their use. The main consequence of the degradation is decrease of its internal energy capacity (Wh) and increase of equivalent serial resistance (ESR).

There are two main mechanisms of batteries ageing, as depicted in FIG. 1. Calendar ageing, related to battery longevity conditioned by SoC level kept on a battery over time and cycle ageing – related to C-rate and number of charging cycles (discharge and charge sessions). The temperature of the battery is an additional ageing factor that has an influence on the calendar ageing as well as on the cycle ageing. However, in the specific application of batteries in the battery energy storage systems (BESS) temperature parameters can be omitted since the batteries the battery energy storage systems (BESS) operate in stable temperature 22-25° C. provided by air-conditioning systems.

It is very important – from exploitation, scheduled maintenance, or investment point of view - to be able to judge battery wearing progress and remaining lifespan, defining how long battery may stay in service. In consequence the initial investment cost, operation cost, cost of service, maintenance schedule and certainty of device with battery can be calculated. However, it is very difficult, due to various chemical compositions, different structures, and exploitation conditions.

Battery manufacturers can predict the lifetime of their products based on their experience in cells designing and manufacturing. The battery manufacturers have knowledge about the mechanism of battery structure degradation and data of battery survivability collected in the laboratory or in-field application (e.g., mobile phone batteries statistics).

However, such lifetime predictions are done assuming standard conditions such as State of Charge (SoC), Depth of Discharge (DoD), charge/discharge rate (C-rate), number of performed cycles, ambient conditions such as temperature and/or humidity and others. Nonetheless, users of the batterie cannot always keep the same operation condition due to varying ambient conditions or utilization needs. Therefore, manufacturers define battery life in a number of charge/discharge cycles assuming the single full cycle is charging and discharging to one defined Depth of Discharge with a nominal C-rate. If one cycle per day is assumed the total lifetime of the battery can be calculated.

Therefore, a number of non-destructive methods helping to judge battery degradation have been elaborated. Most of them use a simple measurement of electrical parameters (e.g., ESR). Some more advanced use thermography or radiography.

Furthermore, in many cases, manufacturers and/or vendors of batteries are forcing on batteries users an execution of the State of Health (SoH) procedure at least once per year for warranty purposes. The goal of the State of Health (SoH) procedure is to investigate the true capacity of the battery, recalibrate SoC and update battery lifetime estimation. The procedure usually is as follows:
a. discharging batteries to minimum
b. 15 min of rest
c. charging to maximum
d. 15 min of rest
e. discharging to minimum

The SoC recalibration procedure is required to mark the battery degradation degree, calculate, and set trendlines for the predicted remaining battery lifespan. It means that this method takes into consideration only the averaged degradation process of the battery in the past period. The described approach cannot distinguish so-called “cycle ageing” or “calendar ageing” as the root cause for battery degradation.

The drawback of this approach is that the expected lifetime is always assumed for typical exploitation conditions and cannot be treated as the advice for the utilization model of the battery for its lifetime optimization.

Furthermore, in some specific applications the controlled, forced discharge is impossible, e.g., in the BESS applications where BESS is not allowed to discharge to the grid. The discharge process (speed, time and depth of discharge) is affected by external load demand. Moreover, it is expected that BESS is 24 h/7 days in service (maintenance periods limited to the absolute minimum).

A patent application CN111753416A discloses a lithium-ion battery RUL (Remaining useful life) prediction method based on two-stage Wiener process. A two-stage Wiener process-based lithium-ion battery RUL prediction method comprises the following steps:
S1: Collecting historical degradation data of lithium-ion batteries;
S2: Estimating the change point of each lithium-ion battery according to the historical degradation data of the lithium-ion battery;
S3: Estimating the hyperparameters based on the EM algorithm based on the data obtained by the estimation of the change point of the lithium-ion battery;
S4: Collecting lithium-ion battery operation monitoring data to determine whether the change point appear;
S5: Updating the model parameters according to the lithium-ion battery operation monitoring data;
S6: Estimating the RUL of the lithium-ion battery based on the data obtained from the change point estimation and the hyperparameter estimation;
S7: Collecting the latest degradation data and put it into the degradation data set;
S8: Repeating steps S4 to S7 to update the model parameters until the lithium-ion battery fails.

A patent application EP3824305A1 reveals a method for determining a maximum duration of use of a battery comprising: selecting a period of use of the battery; obtaining values of degradation factors of the battery during the period of use; determining one or more ageing indicators of the battery based upon the values of degradation factors; identifying intervals of variation of the values of degradation factors during said period of use, each of the one or more ageing indicators being associated with actual intervals of variation which each comprise a minimum value and a maximum value of said degradation factors; and predicting the maximum duration of use based upon the intervals of variation, the one or more ageing indicators, and at least one operating limit of the battery.

Furthermore, a patent application US20170115358A1 reveals a computer implemented method for determining battery degradation including both calendar and cycle ageing characteristics of the battery. The method comprises the step of: collecting, by the computer, individual battery cycling and calendar ageing data including daily charge/discharge profiles; estimating, by the computer, a primary battery capacity for the individual cycling and calendar ageing; evaluating, by the computer, the individual cycling and calendar ageing stability; combining the individual cycling and calendar ageing into an integrated degradation function for the given battery over its entire lifetime by an iterative process starting with a combined original battery capacity, cap(n) which is the battery original capacity minus original cycling and calendar ageing values; and outputting the integrated degradation function.

Moreover, a patent application WO2021044134A1 discloses a method and system for predicting battery degradation. The method comprises measuring a set of variables for a battery; selecting parameters for a degradation model which predicts degradation of the battery and which comprises a calendar ageing component and a cycling ageing component; predicting a predicted degradation value for the battery using the degradation model and the selected parameters; obtaining an estimated degradation value for the battery using the set of measured variables; updating the parameters for the degradation model based on the predicted and estimated degradation values and outputting a final degradation value based on the estimated and predicted degradation values.

A patent application EP3531149A4 reveals an apparatus and a method for estimating capacity retention ratio of secondary battery. A method for estimating a capacity retention rate of a secondary battery included in a battery pack from a degree of calendar ageing and a degree of cycle ageing of the secondary battery, the method comprising: receiving current information and temperature information of the secondary battery from a sensing unit installed in the battery pack in each cycle having a preset time length; activating a first main process; and activating a second main process, wherein the first main process includes: a first subprocess for updating a state of charge of the secondary battery based on the current information; a second subprocess for setting an operation state of the secondary battery to one of cycle state and calendar state based on the current information; a third subprocess for updating a degree of cycle ageing based on the updated state of charge, the current information and the temperature information when the operation state of the secondary battery is set to the cycle state by the second subprocess; and a fourth subprocess for updating a degree of calendar ageing based on the updated state of charge and the temperature information when the operation state of the secondary battery is set to the calendar state by the second subprocess, and the second main process includes estimating the capacity retention rate of the secondary battery based on a predetermined weighting factor, the updated degree of cycle ageing and the degree of calendar ageing.

Furthermore, a patent application EP3273523B1 discloses an apparatus and a method for estimating degree of ageing of secondary battery. The method of estimating a degree of ageing of a secondary battery, the method comprising: (a) determining a current and a temperature of the secondary battery by using a current measuring unit and a temperature measuring unit; (b) determining a state of charge of the secondary battery from the current of the secondary battery; (c) determining an operation state of the secondary battery as one of a calendar state and a cycle state by using the current of the secondary battery; (d) determining a predefined degree-of-calendar-ageing profile corresponding to the determined state of charge and the determined temperature while the secondary battery is in the calendar state, and determining a degree of calendar ageing in the calendar state by applying a cumulative degree-of-ageing model to the determined degree-of-calendar-ageing profile; (e) determining a predefined degree-of-cycle-ageing profile corresponding to the determined state of charge, the determined temperature, and the determined current of the secondary battery while the secondary battery is in the cycle state, and determining a degree of cycle ageing in the cycle state by applying the cumulative degree-of-ageing model to the determined degree-of-cycle-ageing profile; and (f) determining, as the degree of ageing of the secondary battery, a weighted average value that is calculated for the determined degree of calendar ageing and the determined degree of cycle ageing on the basis of calendar time for which the calendar state is maintained and cycle time for which the cycle state is maintained.

### BRIEF SUMMARY OF THE INVENTION

In one general aspect, the present disclosure provides a method allowing for estimating battery degradation of any kind of battery, notably Li-Ion battery in a battery energy storage system (BESS), taking into consideration actual operating conditions of battery.

In one embodiment, the present disclosure describes a computer-implemented method of estimating battery degradation comprising the steps of:
a) acquiring battery parameters, characteristics of calendar ageing wearing coefficient BWC₁ and/or characteristics of cycle ageing wearing coefficient BWC₂ wherein BWC₁ is a function of State of Charge (SoC) and BWC₂ is a function of charging/dis-charging rate (C-rate),
b) acquiring and/or calculating instantaneous values of SoC and C-rate of a battery in a defined period,
c) reading instantaneous values of calendar ageing wearing coefficient BWC₁ and/or instantaneous values of cycle ageing wearing coefficient BWC₂ corresponding to instantaneous values of SoC and C-rate of a battery acquired in step (b), using characteristics of ageing wearing coefficients acquired in step (a), and
d) determining:
   value of calendar ageing wearing index BWI₁ by referring integrated instantaneous values of BWC₁ determined in step (c) to the integrated instantaneous values of BWC₁ for a period of nominal operation time with maximum allowable value of the SoC, and/or
   values of cycle ageing wearing index BWI₂ by referring integrated instantaneous values of BWC₂ determined in step (c) to the integrated instantaneous values of BWC₂ for full battery charging (from SoCₘᵢₙ to SoCₘₐₓ) or discharging (from SoCₘₐₓ to SoCₘᵢₙ) with nominal C-rate, thereby indicating degree of battery degradation.

In one embodiment, the method further comprises a step of determining a total current value of battery wearing index BWI according to equation (E8),

$$B W I = \left[k ⋅ B W {I}_{1} + \left(1 - k\right) ⋅ B W {I}_{2}\right] \qquad \text{(8)}$$

wherein:

k — weight of calendar ageing wearing index BWI₁ (for 0 < k < 1); (1-k) — weight of calendar ageing wearing index BWI₂.

Beneficially, instantaneous values of SoC and C-rate of a battery are acquired from predicted SoC and C-rate profiles based on historical data. It is also beneficial that the characteristics of calendar ageing wearing coefficient BWC₁ and/or the characteristics of cycle ageing wearing coefficient BWC₂ are frequently updated.

In one embodiment, the characteristics of calendar ageing wearing coefficient BWC₁ and/or characteristics of cycle ageing wearing coefficient BWC₂ are tuned using machine learning (ML) algorithms, wherein historical data of the battery operation is used as input data for ML algorithms.

During battery operation data are collected. These data are input for ML that can tune BWC characteristics to better reflect wearing process of battery. What improves battery lifespan prediction (estimation of the battery degradation).

For battery lifespan prediction, beneficially is, when instantaneous values of calendar ageing wearing coefficient BWC1 and/or instantaneous values of cycle ageing wearing coefficient BWC2 are determined for a period of 24 hours.

In one embodiment, the characteristics of calendar ageing wearing coefficient BWC₁ and characteristics of cycle ageing wearing coefficient BWC₂ of the battery are determined based on battery parameters declared by battery manufacturer.

Usefully, the steps of the method being performed by means of a processing employing artificial intelligence and/or machine learning techniques and/or at least one trained algorithm.

In one embodiment, the method is employed for estimating battery degradation of a Li-Ion battery.

In one embodiment, the method is employed for estimating battery degradation in a battery energy storage system (BESS). Furthermore, it is beneficial that the step of acquiring battery parameters also acquiring operating parameters of a battery energy storage system (BESS).

The object of the invention is also a computer program comprising means of program code for performing all steps of the computer-implemented estimating method when said program is running on the computer.

The disclosure also describes a computer-readable medium storing computer-implemented instructions performing all steps of the computer-implemented estimating method implemented on the computer.

The characteristic of calendar ageing wearing coefficient BWC₁ and characteristics of cycle ageing wearing coefficient BWC₂ defines instantaneous battery wearing intensity for current operation condition. The characteristics of BWC₁ and BWC₂ provide information on wearing speed depending on battery’s actual exploitation condition.

The values of calendar ageing wearing index BWI₁ and cycle ageing wearing index BWI₂ indicate a degree of battery degradation in all systems with Li-Ion batteries, in particular, battery energy storage systems (BESS).

The total current value of battery wearing index BWI relates to degree of battery degradation integrating both mechanisms of batteries ageing, including the significance of each of them for battery ageing.

Results of the method can be used for optimization of the operation of a battery energy storage system (BESS) for setting charging/dis-charging C-rate and State of Charge that leads to slower wearing. Moreover, developed method can point out the optimal battery energy storage system (BESS) operating conditions, which will affect batteries lifetime in minimum level.

### BRIEF DESCRIPTION OF THE SEVERAL VIEWS OF THE DRAWING(S)

FIG. 1 shows mechanism of Li-Ion batteries ageing in accordance with the disclosure.

FIG. 2 schematically shows a method of estimating battery degradation according to the invention in accordance with the disclosure.

FIG. 3 shows example characteristic of the battery wear coefficient BWC₁ in function of SoC values in accordance with the disclosure.

FIG. 4 shows example characteristic of the battery wear coefficient BWC₂ in function of C-rate values in accordance with the disclosure.

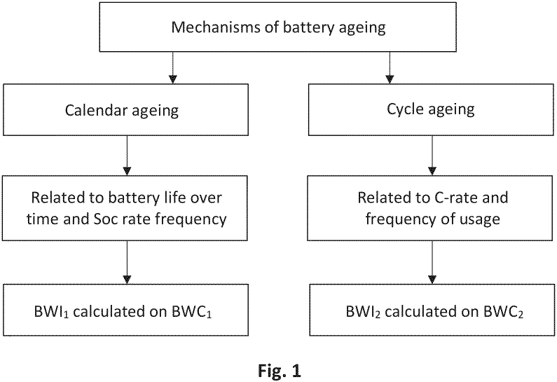

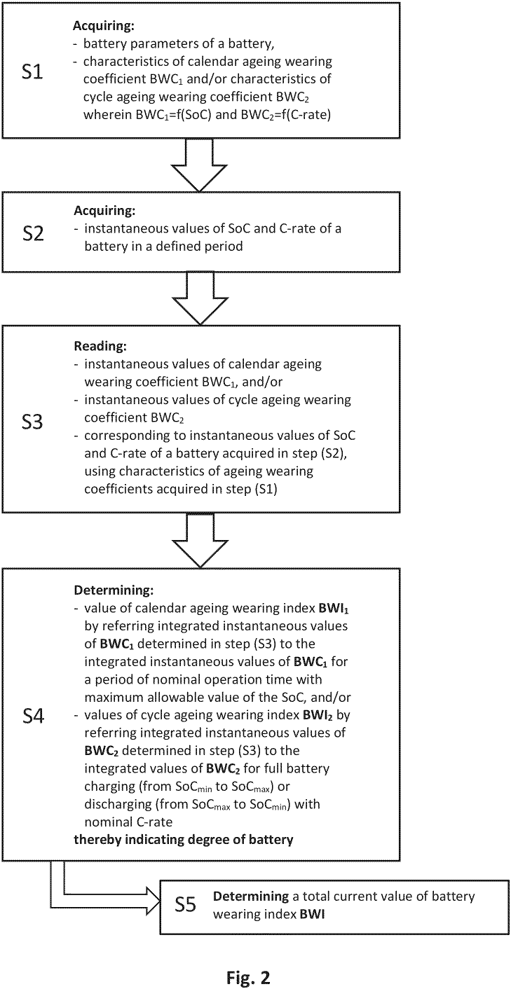

### DETAILED DESCRIPTION OF THE INVENTION

Some parts of the detailed description which is given below are presented as part of procedures, steps of data processing, or other symbolic representations of operations on binary data that can be performed in the computer memory. Therefore, logical steps are performed by the computer, which requires physical manipulation of physical quantities. Typically, these values take the form of electrical or magnetic signals that are suitable for storage, transmission, connection, comparison or other ways of manipulation of data in a computer system. Due to widespread use, these data are referred to as signals, time courses, bits, packets, messages, values, elements, symbols, signs, terms, numbers and the like. In addition, all of these terms, or the like, should be identified with their corresponding physical quantities, and are merely convenient terms for these physical quantities. Terms such as “processing” or “creating”, or “sending”, or “performing”, or “determining”, or “detecting”, or “receiving”, or “selecting”, or “calculating”, or “generating”, or similar, refer to activities and processes of a computer system that manipulates and transforms data represented as physical (electronic) quantities in registers and computer memories into other data similarly represented as physical quantities in memories or registers, or other information storages. The computer-readable medium (memory) as defined herein may typically be non-volatile and/or include a non-volatile device. In this context, the non-volatile storage medium may include a device which may be material, which means that the device has a specific physical form, although the device may change its physical state. Thus, for example, the term non-volatile refers to the device remaining material, although it changes its state.

In addition, data regarding SoC, C-rate, or other quantities, processed by the described method, refer each time to physical measurement and/or predicted data representing the actual operating environment of the battery. In the case of simulation data, there is actually a battery statistically corresponding to this data.

A method of estimating battery degradation is described below. In step S1 of a computer-implemented method of estimating battery degradation in a battery energy storage system (BESS), battery parameters, characteristics of calendar ageing wearing coefficient BWC₁ and/or characteristics of cycle ageing wearing coefficient BWC₂ are acquired S1 from the memory of a battery management system (BMS).

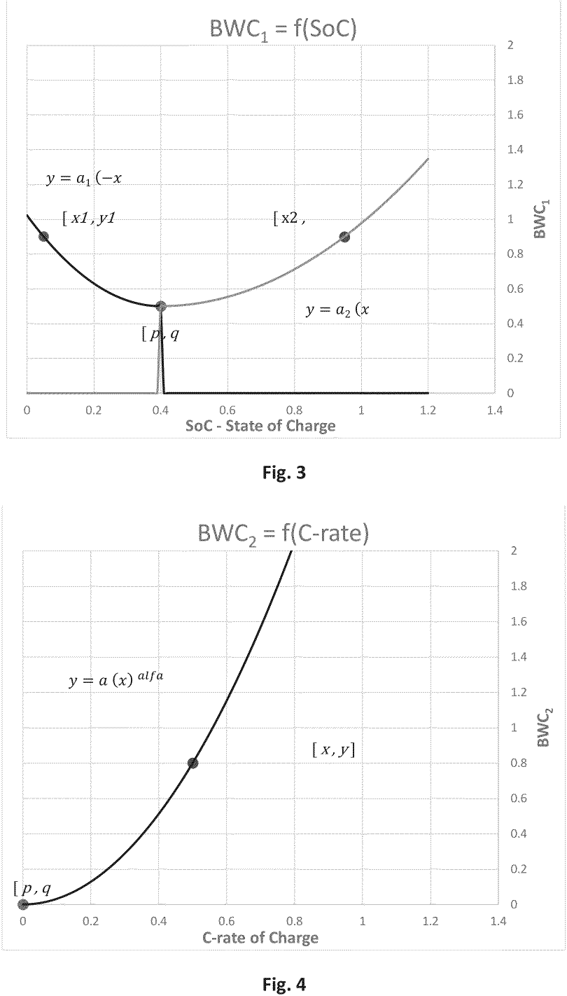

The BWC characteristic defines instantaneous battery wearing intensity for current operation condition of the battery. The BWC characteristics as show on FIG. 3 and FIG. 4 give the information about wearing speed depends on battery’s exploitation condition. This information can be also used for optimization of a selection of charging/dis-charging C-rate and State of Charge that leads to slower wearing. The initial characteristics of calendar ageing wearing coefficient BWC₁ and/or characteristics of cycle ageing wearing coefficient BWC₂ are based on battery type, basic parameters of the battery declared by its manufacturer, as well as recommendations of the manufacturer. Example of battery parameters of a battery acquired in step S1 are shown in Table 1.

TABLE 1

Basic data used for generation of BWCs characteristics

| No. | Index | Value | Short name | Description |
|---|---|---|---|---|
| 1 | SoC_{storage} | 40% | The battery state of charge during long time store | Optimal or recommended State_of _Charge of battery being long time stored. The charge that ensures the battery will be stored with minimal decrease of its initial capacity |
| 2 | SoCₘᵢₙ | 5% | Minimum state of charge | Recommended minimal State_of_Charge remaining in battery considered as the end of discharge. Threshold that never should be crossed to not damage the battery |
| 3 | SoCₘₐₓ | 95% | Maximum state of charge | Recommended maximum State_of_Charge of the battery considered as the end of charge. Threshold that never should be crossed to not damage the battery |
| 4 | DoD | 90% | Depth of Discharge | Discharge in one cycle from Max to Min State_of_Charge |
| 5 | tₛₜₒᵣₑ | 15 years | The store time | How long the battery can be stored on the shelf kept in their optimal storage condition (eg. ensured SoC_{storage}, temperature, humidity, mechanical stress) |
| 6 | t_{life} | 5 years | The life span | How long it is expected the battery can work to their end of life |
| 7 | N_{cycles} | 3000 | The number of cycles | How may full cycles of charge and discharge of the battery can be done during its whole life. |
| 8 | C-rate | 1 | Charge current | Recommended nominal charge/discharge current ratio (for 1 hour). The C-rate is calculated as rated charge/discharge current over-rated capacitance of battery (A/Ah or W/Wh) |

The calendar ageing wearing coefficient BWC₁ relates to “calendar ageing” and is based on the SoC. The function binding BWC₁ to actual value of SoC (BWC1=ƒ(SoC)), has been shown in FIG. 3. The characteristics of the calendar ageing wearing coefficient BWC₁ can be determined by equation (1)

$$B W {C}_{1} = f \left(S o C\right) = \left\{\begin{matrix}{a}_{1} {\left(- x + p\right)}^{a l f a \_ 1} + q , x < S o {C}_{s t o r a g e} \\ {a}_{2} {\left(x - p\right)}^{a l f a \_ 2} + q , x \geq S o {C}_{s t o r a g e}\end{matrix}\right) \qquad \text{(1)}$$

wherein:

x - value of SoC - the argument of the function (1); p - storage SoC (SoC_{storage}) - the argument of minimum value of the function (1); q - quotient of an expected operation time (t_{life}) of the battery over the nominal storage time (tₛₜₒᵣₑ) declared by battery vendor/manufacturer - minimum value of the function (1) set for the argument x = p; alfa_1 -slope coefficient of the curve (alfa_1 >= 1); alfa_2 - slope coefficient of the curve (alfa_2 >= 1); a1 - mathematic coefficient of canonical form of the quadratic equation satisfying condition when function (1) passes through the reference point [x₁, y₁] and point [p, q]; a2 -mathematic coefficient of canonical form of the quadratic equation satisfying condition when function (1) passes through the reference point [x₂, y₂] and point [p, q]

The lowest value of calendar ageing wearing coefficient BWC₁ presented on FIG. 3 is set for SoC value recommended by manufacturer for storing batteries (SoC_{storage}) e.g., 40%. In turn, points [x₁, y₁] and [x₂, y₂] relates to values of BWC₁ corresponding to the SoC of the battery discharged to minimum or charged to maximum. Those points are determined on the basis of the battery manufacturer’s data. Coefficients a₁, a₂ can be defined by equation (2) and equation (3).

$${a}_{1} = \frac{\left(D o D / 100 - q\right)}{{\left(- \left(1 - D o D / 100\right) / 2 + p\right)}^{a l f a \_ 1}} \qquad \text{(2)}$$

$${a}_{2} = \frac{\left(D o D / 100 - q\right)}{{\left(1 - \left(1 - D o D / 100\right) / 2 - p\right)}^{a l f a \_ 2}} \qquad \text{(3)}$$

The values of alfa_1 and alfa_2 for the initial characteristics of BWC₁ is set 2 and the calendar ageing wearing coefficient BWC₁ is thereby described by quadratic function equation.

In turn, the ageing wearing coefficient BWC₂ relates to “cycle ageing” and is based on the actual value of C-rate. The function binding BWC₂ to actual value of C-rate (BWC₂=ƒ(C-rate)), has been shown in FIG. 4. The characteristics of the cycle ageing wearing coefficient BWC₁ can be determined by equation (4).

$$y = a {\left(x\right)}^{a l f a} \qquad \text{(4)}$$

wherein: x - value of SoC; alfa - slope coefficient of the curve (>0); a - mathematic coefficient of the quadratic equation satisfying condition when function (4) passes through the reference point [x, y].

The value of alfa of the initial characteristics of BWC₂ is equal 2 and that ageing wearing coefficient is described by quadratic function equation. The smallest value of BWC₂ coefficient is for C-rate equal to “0”, when current doesn’t flow, and operating cycles are no performed. In turn point [x,y] relates point of nominal wearing. That point is determined on the basis of the battery manufacturer’s data.

Coefficients a can be defined by equation (5).

$$a = \frac{B W {C}_{n o m i n a l w e a r i n g}}{{\left(C - r a t {e}_{n o m i n a l w e a r i n g}\right)}^{a l p h a}} \qquad \text{(5)}$$

The characteristics of calendar ageing wearing coefficient BWC₁ and/or characteristics of cycle ageing wearing coefficient BWC₂ are frequently updated with the use of ML algorithms or AI. Historical data of the battery operation is used as an input data for ML algorithms. In particular, values of alfa can be modified using ML algorithms in order the curves better reflect wearing process of battery.

Mentioned Machine Learning (ML) mechanism is subject to n-dimensional space, in which each successive factor influencing the battery life is one of the n dimensions of space. In this example, 2-dimensional space is considered. However, in the other embodiments more factors influencing the battery life can be considered, like e.g., temperature, air humidity, atmospheric pressure, mechanical deformation, mechanical stress; reactive gases (e.g., ozone); cosmic radiation.

In the next step S2 instantaneous values of SoC and C-rate of a battery for a defined period (e.g., one day - 24 hours) are acquired and/or calculating. In the event of a need for calculation SoC and C-rate values from measured data (eg. battery current), it can be done with well-known methods for the person skilled in the art.

In some embodiments instantaneous values of SoC and C-rate of a battery are acquired from predicted SoC and C-rate profiles based on historical data. Prediction of such profiles is performed by means of a processing employing artificial intelligence and/or machine learning techniques and/or at least one trained algorithm upon historical data of power profiles of a power system comprising said battery.

Then read S3 the instantaneous values of calendar ageing wearing coefficient BWC₁ and/or instantaneous values of cycle ageing wearing coefficient BWC₂ corresponding to instantaneous values of SoC and C-rate of a battery in a battery energy storage system (BESS) acquired in step S2, using characteristics of ageing wearing coefficients acquired in step S1 is performed.

After that the value of calendar ageing wearing index BWI₁ is determined S4 by referring integrated instantaneous values of BWC₁ determined in step S3 to the integrated instantaneous values of BWC₁ for a period of expected operation time with maximum allowable value of the SoC (SoCₘₐₓ). The ageing wearing index BWI₁ is defined by an equation (6).

$$B W {I}_{1} = \frac{\int B W {C}_{S o C \left(t\right)} d t}{{\int }_{\text{o}}^{t l i f e} B W {C}_{\text{SoC} m a x} d t} ∗ 100 \% \qquad \text{(6)}$$

In step S4 also values of cycle ageing wearing index BWI₂ is determined by referring integrated instantaneous values of BWC₂ determined in step S3 to the integrated instantaneous values of BWC₂ for full battery charging (from SoCₘᵢₙ to SoCₘₐₓ) or discharging (from SoCₘₐₓ to SoCₘᵢₙ) with nominal C-rate. The ageing wearing index BWI₁ is defined by an equation (7).

$$B W {I}_{2} = \frac{\int B W {C}_{C - r a t e \left(t\right)} d t}{2 \text{} ⋅ \text{} {N}_{max \_ c y c l e s} {\int }_{S O {C}_{m i n}}^{S o {C}_{m a x}} B W {C}_{C - r a t e} d t} ∗ 100 \% \qquad \text{(7)}$$

wherein: N_{cycles} - the number of full battery charging (from SoCₘᵢₙ to SoCₘₐₓ) or discharging (from SoCₘₐₓ to SoCₘᵢₙ) cycles declared by manufacturer; The values of calendar ageing wearing index BWI₁ and cycle ageing wearing index BWI₂ indicate a degree of battery degradation.

Optionally, in next step S5 a total current value of battery wearing index BWI can be determined according to equation (8),

$$B W I = \left[k ⋅ B W {I}_{1} + \left(1 - k\right) ⋅ B W {I}_{2}\right] \qquad \text{(8)}$$

wherein: k - weight of calendar ageing wearing index BWI₁ (for 0 < k < 1); (1-k) - weight of calendar ageing wearing index BWI₂.

The total current value of battery wearing index BWI relates to degree of battery degradation in integrating both mechanisms of batteries ageing, including the significance of each of them for battery ageing.

Furthermore, all step of said method can be performed by means of a processing employing artificial intelligence and/or machine learning techniques and/or at least one trained algorithm.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and “at least one” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

What is claimed is:

1. A computer-implemented method of estimating battery degradation in a battery energy storage system (BESS), the method comprising:
a) acquiring battery parameters of a battery, characteristics of calendar ageing wearing coefficient BWC1 and/or characteristics of cycle ageing wearing coefficient BWC2 wherein BWC1 is a function of State of Charge (SoC) and BWC2 is a function of charging/dis-charging rate (C-rate),
b) acquiring and/or calculating instantaneous values of SoC and C-rate of a battery in a defined period,
c) reading instantaneous values of calendar ageing wearing coefficient BWC1 and/or instantaneous values of cycle ageing wearing coefficient BWC2, corresponding to instantaneous values of SoC and C-rate of a battery acquired in step (b), using characteristics of ageing wearing coefficients acquired in (a) and
d) determining:
a value of calendar ageing wearing index BWI1 by referring integrated instantaneous values of BWC1 determined in (c) to the integrated nominal values of BWC1 for a period of nominal operation time with maximum allowable value of the SoC, and/or
values of cycle ageing wearing index BWI2 by referring integrated instantaneous values of BWC2 determined in (c) to the integrated nominal values of BWC2 for full battery charging (from SoCmin to SoCmax) or discharging (from SoCmax to SoCmin) with nominal C-rate,
thereby indicating degree of battery degradation.

2. The method according to claim 1, further comprising determining a total current value of battery wearing index BWI according to the following equation:
$$\text{BWI=} \left[〚 \text{k} ⋅ \text{BWI} 〛 \text{\_1+} \left(1 - \text{k}\right) 〚 ⋅ \text{BWI} 〛 \text{\_2}\right]$$
wherein: k is a weight of calendar ageing wearing index BWI1 (for 0 < k < 1 ); and (1-k) is a weight of calendar ageing wearing index BWI2.

3. The method according to claim 1, wherein instantaneous values of SoC and C-rate of a battery are acquired from predicted SoC and C-rate profiles based on the historical data.

4. The method according to claim 1, wherein characteristics of calendar ageing wearing coefficient BWC1 and/or characteristics of cycle ageing wearing coefficient BWC2 are frequently updated.

5. The method according to claim 1, wherein characteristics of calendar ageing wearing coefficient BWC1 and/or characteristics of cycle ageing wearing coefficient BWC2 are tuned using ML algorithms, wherein historical data of the battery operation is used as input data for ML algorithms.

6. The method according claim 1, wherein the characteristics of calendar ageing wearing coefficient BWC1 and characteristics of cycle ageing wearing coefficient BWC2 of the battery are determined based on battery parameters declared by battery manufacturer.

7. The method according to claim 1, wherein the steps of the method are performed by a processing employing artificial intelligence and/or machine learning techniques and/or at least one trained algorithm.

8. The method according to claim 1, wherein the method is employed for estimating battery degradation of a Li-Ion battery.

9. The method according to claim 1, wherein said method is employed for estimating battery degradation of a battery energy storage system (BESS).

10. The method according to claim 9, wherein acquiring battery parameters also includes acquiring operating parameters of a battery energy storage system (BESS).
